(19) United States
(12) Patent Application Publication
(10) Pub. No.: US 2005/0110538 A1
(43) Pub. Date: May 26, 2005

(54) Phase detector and method of generating a phase-shift differential signal

(75) Inventors: Francesco Centurelli, Roma (IT); Massimo Pozzoni, Pavia (IT); Giuseppe Scotti, Latina (IT); Alessandro Trifiletti, Velletri (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.l., Agrate Brianza (MI) (IT)

(21) Appl. No.: 10/837,509

(22) Filed: Apr. 30, 2004

(30) Foreign Application Priority Data
Apr. 30, 2003 (EP) 03425274.2

(51) Int. Cl. H03L 7/06

(52) U.S. Cl. 327/156

(57) ABSTRACT

A phase detector receives an oscillating signal and a clock signal, and outputs a differential signal representing a phase difference therebetween. The phase detector includes a first differential pair of transistors respectively driven by the clock signal and by an inverted clock signal for generating the differential signal. An auxiliary differential pair of transistors is coupled to the first differential pair of transistors and is respectively driven by the oscillating signal and by an inverted oscillating signal. A current generator biases the first differential pair of transistors and the auxiliary differential pair of transistors.

### FIELD OF THE INVENTION

The present invention relates to phase detectors, and in particular, to a method for generating a differential signal representing the phase difference between two input signals, and to a phase detector operating at high frequencies.

### BACKGROUND OF THE INVENTION

In long distance transmission systems operating at high bit rates over standard signal fiber lines, data receivers may receive significantly distorted signals. Inter-symbolic interference, finite bandwidth, fiber nonlinearity and other non-idealities increase the probability of erroneous recognition of a received bit. For these reasons, it is often necessary to place, along the transmission line, data regenerating channel systems that sample a received signal and retransmit it to either a successive data regenerating system or to the end receiver.

The incoming data at the receiver may be considered as a varying analog signal from which a synchronization or clock signal may be recovered. Recovering the clock in the form of a signal that generally oscillates between a higher level and a lower level signal from the incoming signal is essential for sampling it correctly to regenerate the digital data to be transmitted.

Of course, the clock signal could alternatively be transmitted together with the data stream, and the clock can be easily filtered at the receiver. In the majority of cases, the clock must be recovered from the data stream using a phase locked loop (PLL).

FIG. 1 shows a sample architecture of a system for data regeneration. It is substantially composed of a phase-locked loop, which includes a phase detector PD, a loop filter LP and a voltage controlled oscillator VCO. The loop recovers the clock signal CK and provides it to a D-type flip-flop that samples the input signal for outputting a regenerated data stream.

The phase detector PD is input with the digital signal DAT to be regenerated and retransmitted, and the recovered clock CK. The phase detector PD commonly includes a differential stage that outputs a differential signal OUT+, OUT− representing the phase difference between the digital signal DAT and the clock CK. This differential signal is produced by comparing the transition edges of the digital signal and the clock signal.

The loop filter LP is input with the differential signal OUT+, OUT− and generates a control voltage Vc for a voltage controlled oscillator VCO by low pass filtering the differential component of the differential signal OUT+, OUT−. If the control voltage Vc is not null, the VCO adjusts the frequency of the recovered clock CK until the control voltage becomes null.

If the digital signal DAT switches regularly, the phase detector is able to continuously compare the transition edges of the recovered clock CK and the signal DAT. Thus, the recovered clock has a good precision. Differently, when the digital signal is a non-return to zero (NRZ) signal, such as the one depicted in FIG. 2, there may not be transitions for a relatively long time. During these intervals the PLL loop is no longer able to adjust the frequency of the recovered clock.

Many types of phase detectors are available. It is worth mentioning that the classical phase and frequency detector (PFD), the bang-bang detector and the linear phase detector are frequently used.

The PFD detector, shown in FIG. 3, is most commonly used in PLL systems because of its capability of detecting both phase and frequency errors. It comprises two D-type flip-flops. The first flip-flop is clocked by the input signal and the second flip-flop is clocked by the recovered clock generated by the voltage controlled oscillator VCO of the phase-locked loop. When one of these signals undergoes a transition, the output of the respective flip-flop is set. The two flip-flops may be reset only when both are set.

In this mode the flip-flops generate two output pulses. The difference between the duration of these two pulses represents the phase error between the two input signals. The advantage of this detector is its capability of sensing both phase errors and frequency errors, and that its output is proportional to the phase mismatch. A second advantage is that when the two inputs are synchronized, the duration of the output pulses is null and there is no injection into the loop filter, and as a consequence, the litter is minimized. A disadvantage of this architecture is that it does not work when there is an absence of transitions in the input signal, and so it is not usable for regenerating data for a NRZ transmission system.

A possible approach to overcome this limitation is represented by the so-called bang-bang phase detector, the working principle of which is illustrated by the timing diagram of FIG. 4. If a data transition occurs before a clock transition, then this phase detector outputs a fixed-length positive pulse to the loop filter in cascade. In the opposite case, that is, when a data transition occurs after the clock transition, a negative fixed-length pulse value is generated.

The disadvantage of this phase detector is that its output is not proportional to the phase error between data and the clock, i.e., this phase detector has a non-linear transfer function. A system for regenerating data that employs a bang-bang phase detector may continuously oscillate between a phase lead and a phase lag. This increases the frequency jitter of the recovered clock.

Another family of phase detectors is represented by the linear phase detectors like the Hogge phase detectors, which generate a signal proportional to the phase difference of their input signals. Both linear and bang-bang phase detectors exploit a similar working principle, which is as follows. At the transition of the incoming data, a positive or negative current or voltage pulse is output toward the loop filter, depending on whether the data leads or lags the clock. The amplitude of the pulse may be constant (bang-bang phase detectors) or proportional (linear phase detectors) to the phase difference between the data and the clock, as disclosed in the article by Aaron et al., titled “Integrated Fiber-Optic Receivers”, Kluwer Academic Publishers. Unfortunately, it is very difficult to use them when the data rate is relatively high because they are based on the use of flip-flops, which require a certain time for generating a stable output.

### SUMMARY OF THE INVENTION

An object of the present invention is to provide a fast and relatively straightforward phase detector which may be used in a phase-locked loop, and is particularly suited for operating at relatively high data rates based on the use of fast linear (analog) stages.

This and other objects, advantages and features in accordance with the present invention are provided by a phase detector receiving as input a generally oscillating signal, for example a distorted digital data signal, and a clock signal for outputting a differential signal representing the phase difference between the oscillating signal and the clock signal.

The phase detector comprises a first differential pair of transistors respectively driven by the clock signal and by its inverted replica for generating a differential signal corresponding to the currents respectively flowing in the transistors of the first differential pair. At least one auxiliary differential pair of transistors is respectively driven by the generally oscillating signal, and its inverted replica having its common current node is coupled to corresponding current nodes of the first differential pair. A current generator may bias all of the differential pairs.

The output differential signal is non-null only when there is a transition and there is a phase difference. For the time the oscillating input signal does not undergo any transition, the differential signal may remain null.

Although the novel phase detection of this invention is outstandingly fast, as in known phase detectors, if there are long periods of time during which the generally oscillating signal does not switch, the precision of the frequency of the recovered clock may progressively worsen.

According to a preferred embodiment of the invention, the above mentioned problem is addressed by providing the phase detector with a feedback loop that regulates the current generated by the biasing current generator. The loop includes a sensor that monitors the transition density of the generally oscillating input signal, and increases the bias current of the differential transistor pairs when the transition density decreases. The amplitude of the output differential signal increases because of the increased gain of the differential stage, thus making the VCO that is present downstream adjust more promptly the frequency of the recovered clock.

It has been found that the transition density of the oscillating input signal directly affects the time average of the common mode current of the output differential signal, and that an effective feedback loop may be formed by using a sensing circuit of the output common mode current for generating a voltage representative of the transition density of the input oscillating signal, and a correction circuit including an amplifier for amplifying a difference between the representative voltage and a reference value. The feedback loop regulates the gain of the differential pairs to make null this difference.

### BRIEF DESCRIPTION OF THE DRAWINGS

The different aspects and advantages of the invention will appear even more evident through a detailed description of few embodiments and by referring to the attached drawings, wherein:

FIG. 1 illustrates a typical system for regenerating digital data according to the prior art;

FIG. 2 is a sample waveform of a non-return-to-zero digital signal according to the prior art;

FIG. 3 depicts a phase and frequency detector PFD according to the prior art;

FIG. 4 shows the signal waveforms of a bang-bang phase detector according to the prior art;

FIG. 5 shows a basic architecture of a first embodiment of a phase detector in accordance with the invention;

FIG. 6 shows an alternative embodiment of a phase detector in accordance with the invention;

FIG. 7 is a timing diagram illustrating the functioning of the phase detectors of FIGS. 5 and 6; and

FIG. 8 depicts a preferred embodiment of the phase detector in accordance with the invention.

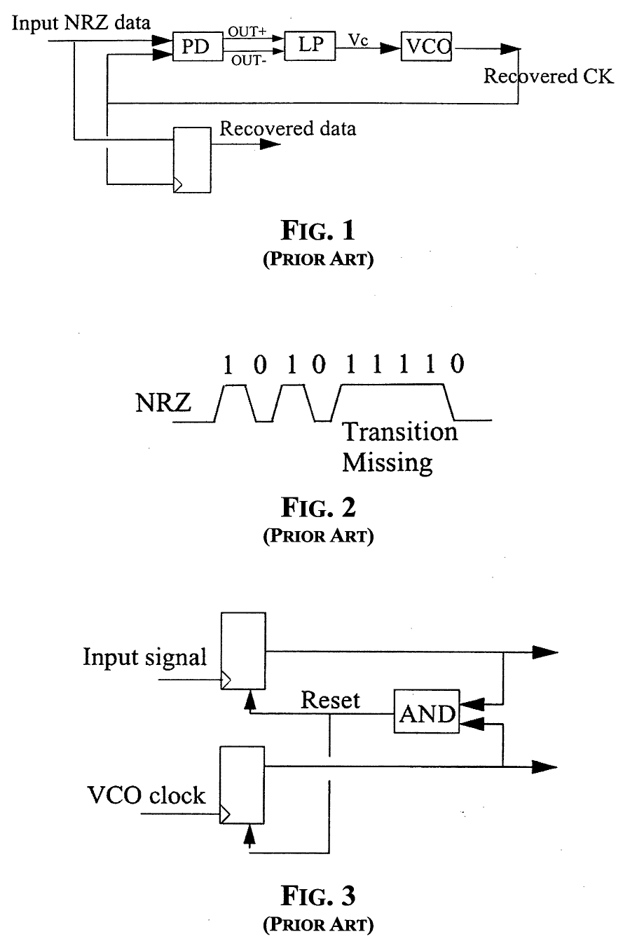

### DETAILED DESCRIPTION OF THE PREFERRED EMBODIMENTS

A first embodiment of a phase detector of the invention is depicted in FIG. 5. The phase detector is substantially composed of first Q3, Q4 and second Q1, Q2 differential pairs of transistors, biased by a common constant current generator Ipd. The first differential pair Q3, Q4 is driven by the recovered clock CK and its inverted replica CKN, while the second pair Q1, Q2 is driven by an input signal DAT and its inverted replica DATN.

In the ensuing description reference will be made to a digital signal DAT, but the same considerations hold for any other generally oscillating signal, such as a sine waveform, a saw-tooth signal and the like. The amplitudes of the signal DAT and the recovered clock CK may be chosen such that when the digital signal DAT is not switching, the second differential pair Q1, Q2 draws the whole current of the generator, while the first differential pair Q3, Q4 does not deliver any output current to the loop filter. For a digital signal DAT switching between a positive +V and a negative voltage −V, this condition is satisfied if the absolute value V is always greater than the maximum absolute voltage level of the recovered clock.

The above mentioned condition is not strictly necessary. As may be easily noticed by an expert technician, the clock amplitude may even surpass the absolute value V of the oscillating input signal if the transistors Q3, Q4 of the first differential pair are provided with appropriate emitter degeneration resistors (not shown in FIG. 5). For sake of simplicity, the ensuing description refers to the case in which there are no emitter degeneration resistors.

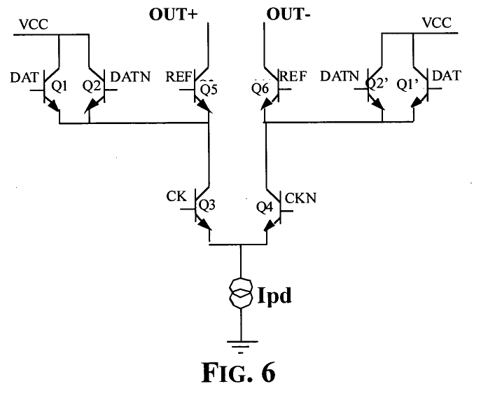

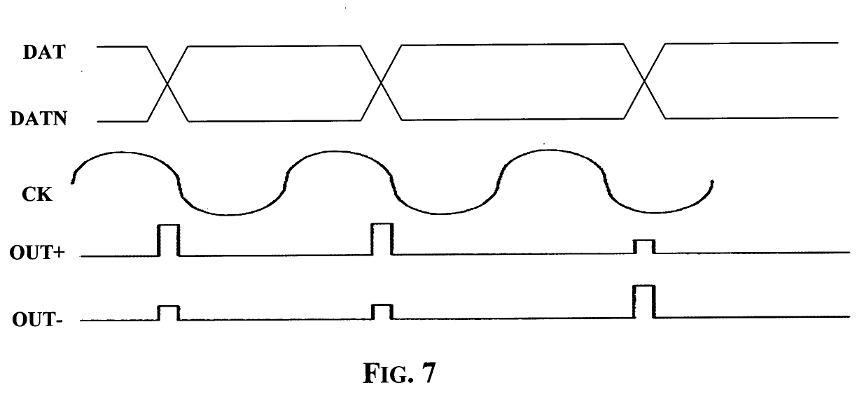

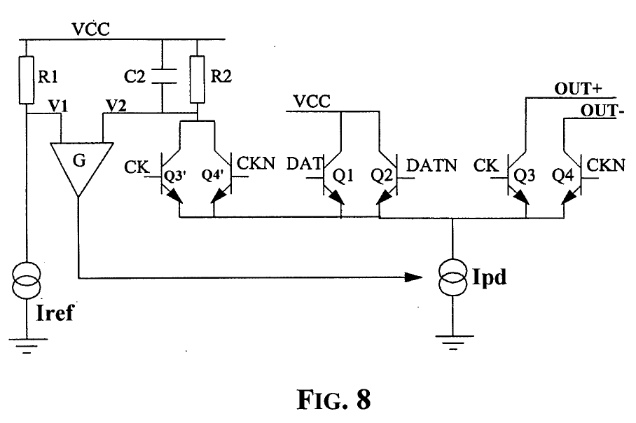

During data transition, because of finite rise and fall times of the digital signal DAT, if the recovered clock is not synchronous with the signal DAT, there will be a time interval during which the differential pair Q3, Q4 absorbs a portion or the whole constant bias current Ipd, as illustrated in FIG. 6 by way of a timing diagram. When the signal DAT does not switch synchronously with the clock signal, there is a short time interval during which the clock CK (or CKN) signal is greater than or comparable to the voltage levels of the digital signal DAT and of its inverted replica DATN. During this time interval a non-null current OUT+ or OUT− flows in the transistor Q3 or Q4.

If at a transition of DAT (DATN) the clock signal CK is higher than CKN, then the current OUT+ is greater than the current OUT−. The opposite situation occurs when at the transition of DAT (DATN) the clock CK is lower than CKN.

By assuming that, because of finite rise and fall times of the oscillating input signal DAT and of its inverted replica DATN, there is a time interval T1 in which a part of the bias current Ipd is absorbed through the transistors Q3 and/or Q4 and that half of the bias current Ipd is absorbed through the differential pair Q1, Q2 and half through the output differential pair Q3, Q4. The total electrical charge flowing in the differential pair Q3, Q4 will be
Ipd*T1/2.

This charge transfer splits itself between the two transistors Q3 and Q4 according to the well known hyperbolic tangent function that characterizes every differential pair. If the phase mismatch between the recovered clock CK and the input signal DAT is relatively small, it is possible to approximate this hyperbolic function with a linear function. Thus, the differential output signal will be approximately proportional to the phase mismatch.

If the bases of the transistors Q3 and Q4 are at the same voltage during a transition of the signal DAT, that is, if the clock is perfectly synchronous with the digital signal DAT, both transistors absorb only a common mode current. This is while the differential mode current, which represents the output of the phase detector, is null.

Should the base voltage of the transistor Q3 be higher (lower) than the base voltage of the transistor Q4 during a transition of the signal DAT, that is, if the recovered clock CK leads (lags) the signal DAT, then a greater (smaller) current will flow in Q3 than in Q4. In this case the phase detector will output a non-null differential signal because the two input signals are out of phase.

The fact that the amplitudes of the output current pulses OUT+ and OUT− of the phase detector of the invention are practically proportional to the delay between the clock CK and the signal DAT, this makes the phase detector particularly suited for realizing phase-locked loops that are capable of recovering accurately the clock from a NRZ data stream. In fact, the phase detector of the invention outputs a null differential signal in the case of phase matching between the input signal DAT and the recovered clock, thus minimizing the frequency jitter of the recovered clock CK.

The phase detector of the present invention may work at very high bit rates (>10 Gb/s) because it is substantially composed of four transistors, which may be either bipolar junction transistors (BJT) or MOSFETs, with relatively short recovery times. These transistors may switch at extremely high frequency.

Moreover, the phase detector of the invention is ideally suited also for NRZ digital input signals, because it does not generate spurious outputs corresponding to missing transitions. In fact, as long as the signal DAT does not switch, the differential pair Q3, Q4 that generates the differential signal OUT+, OUT− remains unable to draw any current from the bias current generator Ipd. This is because the second differential pair Q1, Q2 absorbs the whole bias current of the common current generator.

According to an alternative embodiment, there may be two auxiliary differential pairs Q1, Q2 and Q1′, Q2′ coupled, respectively, to the collector nodes of the transistors Q3, Q4 of the first differential pair according to the circuit diagram of FIG. 6, instead of only one auxiliary differential pair Q1, Q2 connected to the common emitter node as depicted in FIG. 5. However, the principle remains the same. The two differential pairs Q1, Q2 and Q1′, Q2′ are both driven by the same signals DAT and DATN and draw current from the output lines of the first differential pair Q3, Q4. This makes null the differential output signal OUT+ and OUT− when the amplitude of the signal DAT or DATN exceeds the amplitude of the clock CK and its inverted replica CKN.

In addition, output transistors Q5, Q6 are respectively connected in series to the collector nodes of the first differential pair and are both controlled by a control voltage REF for keeping the output transistors Q5, Q6 in a conduction state, at least and preferably only during the transitions of the input signal DAT. This may be ensured simply by choosing a control voltage REF between the maximum and the minimum values of the oscillating signal DAT.

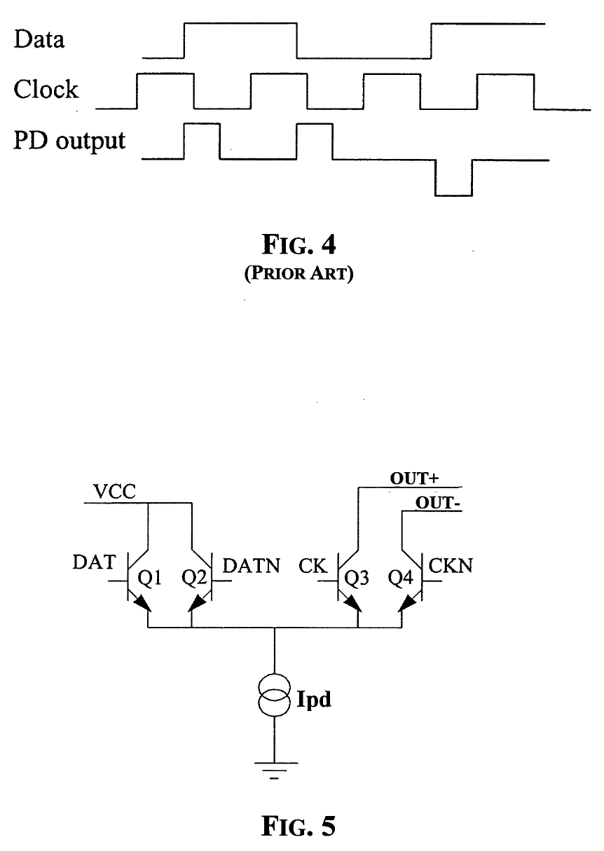

Let us suppose that the oscillating input signal DAT is a digital signal, such as that of FIG. 2. It may happen that the signal DAT does not undergo transitions for long periods of time, and as discussed above, the precision of the frequency of the clock recovered by a PLL employing a phase detector of the invention may decrease in presence of these relatively long periods of no transitions (i.e., no oscillations of the input signal).

To reduce the loss of precision that may be caused by a decrease of the transition density, a phase detector with a variable gain is employed and the gain is increased as the transition density decreases. In this way, the VCO downstream of the phase detector receives a control voltage Vc of enhanced amplitude and adjusts more promptly the frequency of the recovered clock.

Accordingly, the phase detectors of the invention depicted in FIGS. 5 and 6 may be optionally provided with such a feedback loop composed of sensing means for generating a signal V2 representative of the transition density of the oscillating input signal, and a correction circuit. The correction circuit includes an amplifier for amplifying a difference between the signal V2 and a certain reference value V1. The feedback loop regulates the bias current Ipd to make the representative signal V2 equal to the reference value V1.

As noted, several sensing means or circuits for detecting the transition density are known and may be formed, for example, by a counter that counts clock pulses between successive transitions of the oscillating input signal, and by a circuit that generates a signal V2 representative of a time average of these counts.

According to one aspect of a phase detector of the invention, at least a differential stage for outputting a differential current OUT+and OUT− representative of the phase difference between the oscillating input signal DAT and the recovered clock CK is used. This sensing circuit may be implemented in a straightforward manner by generating a representative signal Vs as a function of the time average of the output common mode current.

It has been found that, when the input signal does not switch (oscillates), the differential output signal is null. Thus, the time average of the output common mode decreases as the transition density decreases.

Preferably, the signal V2 representative of the transition density of the oscillating input signal DAT is obtained by low pass filtering the common mode component of the differential output signal. This signal V2 is compared with a reference value V1, and the gain of the phase detector is regulated in a feedback mode to make the signal V2 equal to V1 by regulating the bias current of the differential pair that generates the output differential signal OUT+, OUT−.

Accordingly, a preferred embodiment of the phase detector of the invention is depicted in FIG. 8. The phase detector is composed of a first differential pair Q3, Q4 controlled by the clock CK and by its inverted replica CKN for outputting the differential signal OUT+, OUT−, and a second differential pair Q1, Q2 controlled by the digital input signal DAT and by its inverted replica DATN. The two differential pairs are biased by a common current generator Ipd, the current of which is regulated by a feedback loop.

The regulation loop is implemented by adding a third differential pair of transistors Q3′, Q4′ that may be identical or scaled replicas of the transistors Q3, Q4 of the first (output) differential pair. These transistors are similarly driven by CK and CKN, such that the currents flowing in the transistors Q3′ and Q4′ are equal or proportional to the currents flowing in the corresponding output transistors Q3, Q4 of the first differential pair. The output common mode current flowing in the differential pair Q3′, Q4′ is forced through a low pass filter R2, C2, for generating a voltage V2 representative of the time average of the output common mode. current of the phase detector, and thus of the transition density of the input signal.

The voltage V2 is applied to a first input of an error amplifier G. The other input of the error amplifier G receives a reference voltage V1 that may be obtained by forcing a reference current Iref through a resistor R1. The error amplifier G regulates the current Ipd generated by the common bias generator for all three differential pairs to make V2 equal V1.

In periods of time during which the input digital signal DAT ceases to switch, the voltage V2 on the low-pass filter R2, C2 decreases. This signals that the time average of the common mode current forced through the filter is diminishing. The high gain differential error amplifier G input with the voltages V1 and V2 regulates the current Ipd that biases all three differential pairs of transistors to make null the difference between V2 and V1.

When a transition occurs after a long sequence of substantially equal input values, the transistors Q3 and Q4 of the first differential pair are biased with a relatively enhanced bias current. The gain of the differential stage is at a correspondingly enhanced level.

Even the phase detector of FIG. 6 may be provided with a feedback loop for regulating the bias current (gain) as a function of the transition density. Also in this case, the sensing circuit may be realized by using an additional pair of transistors Q5′ and Q6′ identical to or scaled replicas of the output differential pair of transistors Q5-Q6, and having their respective emitter (or source) nodes connected to the corresponding emitter (or source) nodes of the output transistors Q5 or Q6, and controlled by the same control voltage REF such that the currents flowing through the transistors Q5′ and Q6′ be equal or proportional to the currents flowing through the corresponding output transistors Q5 and Q6. These currents are eventually summed and forced through a low pass filter for generating a voltage signal V2 similarly to the already described embodiment of FIG. 8.

1-15. (canceled)

16. A phase detector comprising:
a first differential pair of transistors respectively driven by a clock signal and by an inverted clock signal for generating a differential output signal representing a phase difference therebetween;
at least one auxiliary differential pair of transistors coupled to said first differential pair of transistors and being respectively driven by an oscillating signal and by an inverted oscillating signal; and
a current generator for biasing said first differential pair of transistors and said at least one auxiliary differential pair of transistors.

17. A phase detector according to claim 16, wherein said first differential pair of transistors includes first and second output nodes; and wherein said at least one auxiliary differential pair of transistors comprises first and second auxiliary differential pairs of transistors respectively coupled to the first and second output nodes.

18. A phase detector according to claim 17, further comprising a pair of output transistors respectively coupled to the first and second output nodes of said first differential pair of transistors, each transistor of said pair of output transistors having a control terminal for receiving a reference voltage, the reference voltage having a value between maximum and minimum voltages of the oscillating signal.

19. A phase detector according to claim 16, wherein said current generator comprises a regulated bias current generator for generating a bias current; the phase detector further comprising a feedback loop for regulating said bias current generator and comprising:
a sensing circuit for generating a representative signal corresponding to a transition density of the oscillating signal; and
a bias correction circuit connected to said sensing circuit and comprising an error amplifier for amplifying a difference between the representative signal and a second reference voltage for regulating the bias current so that the difference is null.

20. A phase detector according to claim 19, wherein the representative signal is generated as a function of a time averaged common mode component of the differential output signal.

21. A phase detector according to claim 19, wherein said sensing circuit comprises:
a replica differential pair of transistors coupled to said at least one auxiliary differential pair of transistors, said replica differential pair of transistors having a size proportional to a size of said first differential pair of transistors; and
a filter coupled to said replica differential pair of transistors at a common node defined therebetween, said filter receiving as input current to be conducted therethrough, and a voltage at the common node forms the representative signal.

22. A phase detector according to claim 18, wherein said current generator comprises a regulated bias current generator for generating a bias current; the phase detector further comprising a feedback loop for regulating said bias current generator and comprising:
a sensing circuit for generating a representative signal corresponding to a transition density of the oscillating signal, said sensing circuit comprising
a replica differential pair of transistors coupled to said first auxiliary differential pair of transistors, said replica differential pair of transistors having a size proportional to a size of said pair of output transistors, the transistors of said replica differential pair of transistors comprising control terminals receiving the fixed voltage, and first conducting terminals respectively coupled to conducting terminals of the transistors of said pair of output transistors, and
a filter coupled to said replica differential pair of transistors at a common node defined therebetween, said filter receiving as input current to be conducted therethrough, and a voltage at the common node forms the representative signal; and
a bias correction circuit connected to said sensing circuit and comprising an error amplifier for amplifying a difference between the representative signal and a second reference voltage for regulating the bias current so that the difference is null.

23. A phase detector according to claim 16, wherein an amplitude of the oscillating signal is greater than an amplitude of the clock signal.

24. A phase detector according to claim 16, wherein the oscillating signal is a digital signal switching between a positive voltage level and a negative voltage level.

25. A phase detector according to claim 16, wherein the transistors of said first differential pair of transistors and said at least one auxiliary differential pair of transistors comprise bipolar transistors.

26. A phase detector according to claim 16, wherein the transistors of said first differential pair of transistors and said at least one auxiliary differential pair of transistors comprise MOS transistors.

27. A phase-locked loop comprising:
a phase detector comprising
a first differential pair of transistors respectively driven by a clock signal and by an inverted clock signal for generating a differential output signal representing a phase difference therebetween,
at least one auxiliary differential pair of transistors coupled to said first differential pair of transistors and being respectively driven by an oscillating signal and by an inverted oscillating signal, and
a current generator for biasing said first differential pair of transistors and said at least one auxiliary differential pair of transistors;
a loop filter receiving the differential output signal and generating a control voltage; and
a voltage controlled oscillator controlled by the control voltage and generating the clock signal, the clock signal having a frequency proportional to the control voltage.

28. A phase-locked loop according to claim 27, wherein said first differential pair of transistors includes first and second output nodes; and wherein said at least one auxiliary differential pair of transistors comprises first and second auxiliary differential pairs of transistors respectively coupled to the first and second output nodes.

29. A phase-locked loop according to claim 28, wherein said phase detector further comprises a pair of output transistors respectively coupled to the first and second output nodes of said first differential pair of transistors, each transistor of said pair of output transistors having a control terminal for receiving a reference voltage, the reference voltage having a value between maximum and minimum voltages of the oscillating signal.

30. A phase-locked loop according to claim 27, wherein said current generator comprises a regulated bias current generator for generating a bias current; the phase detector further comprising a feedback loop for regulating said bias current generator and comprising:
a sensing circuit for generating a representative signal corresponding to a transition density of the oscillating signal; and
a bias correction circuit connected to said sensing circuit and comprising an error amplifier for amplifying a difference between the representative signal and a second reference voltage for regulating the bias current so that the difference is null.

31. A phase-locked loop according to claim 30, wherein the representative signal is generated as a function of a time averaged common mode component of the differential output signal.

32. A phase-locked loop according to claim 30, wherein said sensing circuit comprises:
a replica differential pair of transistors coupled to said at least one auxiliary differential pair of transistors, said replica differential pair of transistors having a size proportional to a size of said first differential pair of transistors; and
a filter coupled to said replica differential pair of transistors at a common node defined therebetween, said filter receiving as input current to be conducted therethrough, and a voltage at the common node forms the representative signal.

33. A phase-locked loop according to claim 29, wherein said current generator comprises a regulated bias current generator for generating a bias current; said phase detector further comprising a feedback loop for regulating said bias current generator and comprising:
a sensing circuit for generating a representative signal corresponding to a transition density of the oscillating signal, said sensing circuit comprising
a replica differential pair of transistors coupled to said first auxiliary differential pair of transistors, said replica differential pair of transistors having a size proportional to a size of said pair of output transistors, the transistors of said replica differential pair of transistors comprising control terminals receiving the fixed voltage, and first conducting terminals respectively coupled to conducting terminals of the transistors of said pair of output transistors, and
a filter coupled to said replica differential pair of transistors at a common node defined therebetween, said filter receiving as input current to be conducted therethrough, and a voltage at the common node forms the representative signal; and
a bias correction circuit connected to said sensing circuit and comprising an error amplifier for amplifying a difference between the representative signal and a second reference voltage for regulating the bias current so that the difference is null.

34. A phase-locked loop according to claim 27, wherein an amplitude of the oscillating signal is greater than an amplitude of the clock signal.

35. A phase-locked loop according to Claim 27, wherein the oscillating signal is a digital signal switching between a positive voltage level and a negative voltage level.

36. A system for regenerating data comprising:
a phase-locked loop receiving a digital data signal and generating a recovered clock signal in phase with the digital data signal, said phase-locked loop comprising
a phase detector comprising
a first differential pair of transistors respectively driven by a clock signal and by an inverted clock signal for generating a differential output signal,
at least one auxiliary differential pair of transistors coupled to said first differential pair of transistors and being respectively driven by the digital data signal and by an inverted digital data signal, and
a current generator for biasing said first differential pair of transistors and said at least one auxiliary differential pair of transistors;
a loop filter receiving the differential output signal and generating a control voltage; and
a voltage controlled oscillator controlled by the control voltage and generating the clock signal, the clock signal having a frequency proportional to the control voltage; and
a flip-flop receiving the digital data signal and the recovered clock signal, and outputting a regenerated digital data signal by sampling the digital data signal with the recovered clock signal.

37. A system according to claim 36, wherein said first differential pair of transistors includes first and second output nodes; and wherein said at least one auxiliary differential pair of transistors comprises first and second auxiliary differential pairs of transistors respectively coupled to the first and second output nodes.

38. A system according to claim 37, wherein said phase detector further comprises a pair of output transistors respectively coupled to the first and second output nodes of said first differential pair of transistors, each transistor of said pair of output transistors having a control terminal for receiving a reference voltage, the reference voltage having a value between maximum and minimum voltages of the digital data signal.

39. A system according to claim 36, wherein said current generator comprises a regulated bias current generator for generating a bias current; the phase detector further comprising a feedback loop for regulating said bias current generator and comprising:
a sensing circuit for generating a representative signal corresponding to a transition density of the digital data signal; and
a bias correction circuit connected to said sensing circuit and comprising an error amplifier for amplifying a difference between the representative signal and a second reference voltage for regulating the bias current so that the difference is null.

40. A system according to claim 39, wherein the representative signal is generated as a function of a time averaged common mode component of the differential output signal.

41. A system according to claim 39, wherein said sensing circuit comprises:
a replica differential pair of transistors coupled to said at least one auxiliary differential pair of transistors, said replica differential pair of transistors having a size proportional to a size of said first differential pair of transistors; and
a filter coupled to said replica differential pair of transistors at a common node defined therebetween, said filter receiving as input current to be conducted therethrough, and a voltage at the common node forms the representative signal.

42. A system according to claim 38, wherein said current generator comprises a regulated bias current generator for generating a bias current; said phase detector further comprising a feedback loop for regulating said bias current generator and comprising:
a sensing circuit for generating a representative signal corresponding to a transition density of the digital data signal, said sensing circuit comprising
a replica differential pair of transistors coupled to said first auxiliary differential pair of transistors, said replica differential pair of transistors having a size proportional to a size of said pair of output transistors, the transistors of said replica differential pair of transistors comprising control terminals receiving the fixed voltage, and first conducting terminals respectively coupled to conducting terminals of the transistors of said pair of output transistors, and
a filter coupled to said replica differential pair of transistors at a common node defined therebetween, said filter receiving as input current to be conducted therethrough, and a voltage at the common node forms the representative signal; and
a bias correction circuit connected to said sensing circuit and comprising an error amplifier for amplifying a difference between the representative signal and a second reference voltage for regulating the bias current so that the difference is null.

43. A system according to claim 36, wherein an amplitude of the digital data signal is greater than an amplitude of the clock signal.

44. A system according to claim 36, wherein the digital data signal switches between a positive voltage level and a negative voltage level.

45. A method for generating a differential output signal representing a phase difference between an oscillating signal and a clock signal applied to respective inputs of a phase detector comprising a first differential pair of transistors respectively driven by the clock signal and by an inverted clock signal for generating the differential output signal; at least one auxiliary differential pair of transistors coupled to the first differential pair of transistors and being respectively driven by the oscillating signal and by an inverted oscillating signal; a current generator for generating a bias current for biasing the first differential pair of transistors and the at least one auxiliary differential pair of transistors; and a feedback loop for regulating the current generator, the method comprising:
generating a representative signal corresponding to a transition density of the oscillating signal;
amplifying a difference between the representative signal and a second reference voltage for regulating the bias current so that the difference is null; and
generating the differential output signal based upon the regulated bias current.

46. A method according to claim 45, further comprising generating the representative signal as a function of a time averaged common mode component of the differential output signal.

47. A method according to claim 45, wherein the first differential pair of transistors includes first and second output nodes; and wherein the at least one auxiliary differential pair of transistors comprises first and second auxiliary differential pairs of transistors respectively coupled to the first and second output nodes.

48. A method according to claim 47, further comprising a pair of output transistors respectively coupled to the first and second output nodes of the first differential pair of transistors, each transistor of the pair of output transistors having a control terminal for receiving a reference voltage, the reference voltage having a value between maximum and minimum voltages of the oscillating signal.

49. A method according to claim 45, wherein the representative signal is generated using a sensing circuit; and wherein amplifying the difference between the representative signal and the second reference voltage is performed using an error amplifier.

50. A method according to claim 49, wherein the sensing circuit comprises:
a replica differential pair of transistors coupled to the at least one auxiliary differential pair of transistors, the replica differential pair of transistors having a size proportional to a size of the first differential pair of transistors; and
a filter coupled to the replica differential pair of transistors at a common node defined therebetween, the filter receiving as input current to be conducted therethrough, and a voltage at the common node forms the representative signal.

51. A method according to claim 45, wherein an amplitude of the oscillating signal is greater than an amplitude of the clock signal.

52. A method according to claim 45, wherein the oscillating signal is a digital signal switching between a positive voltage level and a negative voltage level.

53. A method according to claim 45, wherein the transistors of the first differential pair of transistors and the at least one auxiliary differential pair of transistors comprise bipolar transistors.

54. A method according to claim 45, wherein the transistors of the first differential pair of transistors and the at least one auxiliary differential pair of transistors comprise MOS transistors.
